(19) United States
(12) Patent Application Publication
(10) Pub. No.: US 2024/0405142 A1
(43) Pub. Date: Dec. 5, 2024

(54) NOVEL TOPCON CELL STRUCTURE AND PREPARATION METHOD THEREOF

(71) Applicant: SOLARSPACE NEW ENERGY (CHUZHOU) CO., LTD., Chuzhou City (CN)

(72) Inventors: Ping FENG, CHUZHOU CITY (CN); Qiangqiang LI, CHUZHOU CITY (CN); Zhaomin CHEN, CHUZHOU CITY (CN)

(21) Appl. No.: 18/731,152

(22) Filed: May 31, 2024

Related U.S. Application Data
(63) Continuation of application No. PCT/CN2024/096694, filed on May 31, 2024.

(30) Foreign Application Priority Data
May 31, 2023 (CN) 202310627201.3

(51) Int. Cl. H01L 31/068; H01L 31/02; H01L 31/0224; H01L 31/028; H01L 31/18

(52) U.S. Cl. CPC H01L 31/068; H01L 31/0201; H01L 31/022441; H01L 31/028; H01L 31/182

(57) ABSTRACT

A solar cell structure comprises a substrate including a front side and a back side. A first tunnel oxide layer, a first polycrystalline silicon layer, a first silicon nitride layer, and a plurality of first electrodes are sequentially formed on the front side of the substrate. A second tunnel oxide layer, a second polycrystalline silicon layer, a second silicon nitride layer, and a plurality of second electrodes are sequentially formed on the back side of the substrate.

### CROSS-REFERENCE TO RELATED APPLICATIONS

This application is a continuation application of International Patent Application No. PCT/CN2024/096694, filed on May 31, 2024, which claims priority to Chinese Patent Application No. 202310627201.3, filed with the China National Intellectual Property Administration on May 31, 2023, and entitled “Novel TOPCon Cell Structure and Preparation Method Thereof”. The above-referenced applications are incorporated herein by reference in their entirety.

### TECHNICAL FIELD

The present invention relates to the field of solar cells, and in particular, to a TOPCon cell structure and a preparation method thereof.

### BACKGROUND

Solar energy, as a clean and renewable source of energy, is inexhaustible. The development and utilization of solar energy can greatly reduce environmental pollution while providing ample energy for humanity. Compared to other renewable energies such as wind, geothermal, and tidal energy, solar energy is widely utilized due to its high availability, extensive resource distribution, and safety and reliability, making it one of the most promising energy sources.

Tunnel oxide passivated contact (TOPCon) cells have been employed to convert solar energy into electrical energy. The TOPCon cells involve growing a tunnel oxide layer on the surface of the silicon wafer for passivation purpose, followed by depositing another layer of doped polycrystalline silicon on the tunnel oxide layer to collect current. However, existing TOPCon cells only have a tunnel oxide layer and polycrystalline silicon layer arranged on the back side, not on the front side. In particular, existing TOPCon cell structures include a substrate, with a P-type doped monocrystalline silicon layer, a front passivation layer, and silver-aluminum electrodes sequentially formed on the front side of the substrate, and sequentially arranged with a tunnel layer, an N-type polycrystalline silicon layer, a back passivation layer, and silver electrodes sequentially formed on the back side of the substrate. By arranging silver-aluminum electrodes on the front side of the substrate and silver electrode on the back side, the TOPCon cell features high conversion efficiency, high bifaciality, high temperature stability, and excellent performance under low-light conditions.

To enhance current collection capacity, existing TOPCon cells require the printing of silver paste on the front busbars and silver-aluminum paste on the front fingers, and silver paste on the back side of the substrate. After printing the paste, drying and sintering processes are performed to form electrodes. Existing TOPCon cells only have a tunnel oxide layer and a polycrystalline silicon layer on the back side, and in the case of N-type silicon wafers, the polycrystalline silicon is doped with phosphorus, necessitating the use of silver electrodes for contact. However, the use of silver paste is very costly. Thus, there is no tunnel oxide layer and polycrystalline silicon layer on the front side of existing TOPCon cells, and highly corrosive aluminum paste, which can damage the cell structure, cannot be used for forming electrodes on the front side of the cell unless it is mixed with silver to form a silver-aluminum paste.

### SUMMARY

The objective of this invention is to provide a TOPCon cell structure and a preparation method thereof that can significantly reduce the production costs of TOPCon cells, thereby enhancing product competitiveness.

To achieve the above objectives, the present invention provides a TOPCon cell structure and a preparation method thereof. According to a first aspect, a TOPCon cell structure is provided, including a substrate comprising a front side and a back side. A first tunnel oxide layer, a first polycrystalline silicon layer, a first silicon nitride layer, and a plurality of first electrodes are sequentially formed on the front side of the substrate. A second tunnel oxide layer, a second polycrystalline silicon layer, a second silicon nitride layer, and a plurality of second electrodes are sequentially formed on the back side of the substrate.

In one or more embodiments, the first polycrystalline silicon layer is an N-type polycrystalline silicon layer, and the second polycrystalline silicon layer is a P-type polycrystalline silicon layer.

In one or more embodiments, the plurality of first electrodes comprise a plurality of silver fingers, and the plurality of second electrodes comprise a plurality of aluminum fingers.

In one or more embodiments, the plurality of first electrodes further comprise a plurality of first silver busbars, and the plurality of second electrodes further comprise a plurality of second silver busbars. The plurality of first silver busbars are perpendicular to the plurality of silver fingers, and the plurality of second silver busbars are perpendicular to the plurality of aluminum fingers

In one or more embodiments, the substrate is a P-type monocrystalline silicon substrate.

In one or more embodiments, a thickness of each of the plurality of silver fingers is in a range of 6 μm to 14 μm.

In one or more embodiments, a thickness of each of the plurality of aluminum fingers is in a range of 6 μm to 30 μm.

In one or more embodiments, a width of each of the plurality of silver fingers is in a range of 15 μm to 35 μm.

In one or more embodiments, a width of each of the plurality of aluminum fingers is in a range of 15 μm to 170 μm.

In one or more embodiments, the substrate is an N-type monocrystalline silicon substrate.

In one or more embodiments, a thickness of each of the plurality of silver fingers is in a range of 6 μm to 14 μm.

In one or more embodiments, a thickness of each of the plurality of aluminum fingers is in a range of 6 μm to 30 μm.

In one or more embodiments, a width of each of the plurality of silver fingers is in a range of 15 μm to 35 μm.

In one or more embodiments, a width of each of the plurality of aluminum fingers is in a range of 15 μm to 170 μm.

According to a second aspect, a preparation method of a TOPCon cell structure is provided. The preparation method comprises: providing a substrate comprising a front side and a back side; forming a first tunnel oxide layer on the front side of the substrate; depositing a first polycrystalline silicon layer on the first tunnel oxide layer; forming a second tunnel oxide layer on the back side of the substrate; depositing a second polycrystalline silicon layer on the second tunnel oxide layer; forming a first silicon nitride layer on the first polycrystalline silicon layer and a second silicon nitride layer on the second polycrystalline silicon layer; and forming a plurality of first electrodes on the first silicon nitride layer and a plurality of second electrodes on the second silicon nitride layer.

The primary distinction of the TOPCon cells provided in the present invention is that they not only have a tunnel oxide layer and doped polycrystalline silicon layer on the back side but also on the front side. That is, tunnel oxide passivating contacts are arranged on both the front side and back side of the cells. This means that the polycrystalline silicon on both sides must be of opposite types, one being P-type and the other being N-type. Aluminum electrodes can be directly formed on P-type polycrystalline silicon. The contact performance between aluminum electrodes and P-type polycrystalline silicon is excellent. In addition, with the protection of the tunnel oxide layer and polycrystalline silicon, the highly corrosive aluminum electrodes will not damage the cell structure.

Compared to existing technology, the TOPCon cell structure and the preparation method thereof according to this invention have the following advantages. Firstly, the production costs of TOPCon cells are significantly reduced, thereby enhancing product competitiveness. Secondly, the P-type polycrystalline silicon has more holes, and the aluminum paste has strong reducibility, leading to better contact between the P-type polycrystalline silicon and the aluminum paste, thereby reducing the Ag/P+-Si ohmic contact problem. Thirdly, replacing silver paste with aluminum paste does not increase the difficulty of electrode matching, and the yield rate does not easily change during production. Fourthly, replacing the silver paste layer with an aluminum paste layer does not produce additional waste gases during drying, thus allowing the utilization of existing equipment for waste gas treatment without increasing waste gas treatment costs. Fifthly, by adjusting the cross-sectional area of the aluminum electrode, the difference in conductivity between silver and aluminum can be reduced. Sixthly, in conventional diffusion preparation of PN junctions, the process is often paired with selective emitter (SE) techniques to improve conversion efficiency, which involves forming local heavy doping at the location of metal grid lines and light doping elsewhere. The new process provided in this invention has an electron transport channel, eliminating the need for selective emitter techniques and reducing machine costs.

### BRIEF DESCRIPTION OF DRAWINGS

FIG. 1 is a schematic diagram of a TOPCon cell structure according to an embodiment of the present invention.

FIG. 2 is another schematic diagram of a TOPCon cell structure according to an embodiment of the present invention.

FIG. 3 is a flowchart of an electrode preparation method for a TOPCon cell structure according to an embodiment of the present invention.

FIG. 4 is a flowchart of a preparation method for a TOPCon cell structure according to an embodiment of the present invention.

The reference numerals in the specification are as follows:
1: P-type monocrystalline silicon substrate; 2: N-type monocrystalline silicon substrate; 3: silver electrode; 4: aluminum electrode; 5: first tunnel oxide layer; 6: N-type polycrystalline silicon layer; 7: first silicon nitride layer; 8: second tunnel oxide layer; 9: p-type polycrystalline silicon layer; 10: second silicon nitride layer.

### DESCRIPTION OF EMBODIMENTS

The specific embodiments of the present invention will be described in detail below with reference to the drawings, but it should be understood that the scope of protection of the present invention is not limited by the specific embodiments.

Unless otherwise explicitly indicated, throughout the specification and claims, terms such as “comprising” or its variations, such as “includes” or “having”, will be understood to include the stated elements or components but not exclude other elements or components.

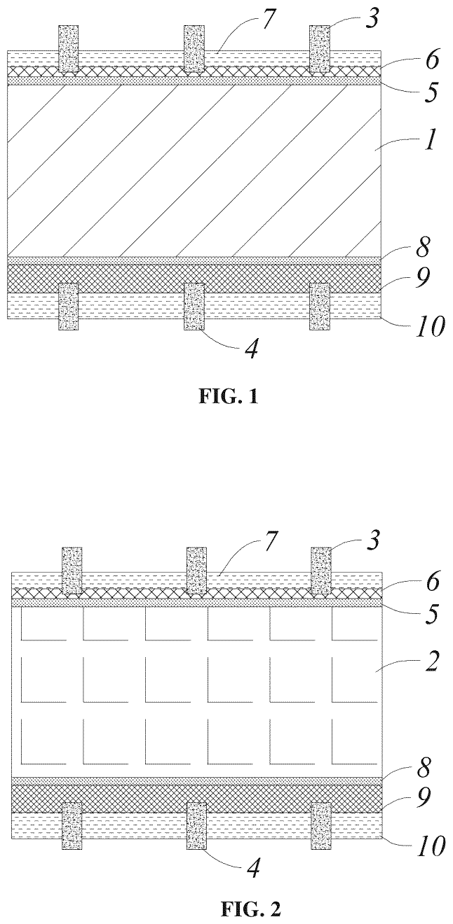

As shown in FIG. 1 and FIG. 2, according to an embodiment of the present invention, a TOPCon cell structure includes a substrate. The substrate includes a front side and a back side. The front side is arranged with a plurality of silver electrodes 3, and the back side is arranged with a plurality of aluminum electrodes 4. The silver electrodes 3 and the aluminum electrodes 4 are formed by screen printing technology. The silver electrodes 3 are formed by printing silver paste on the front side of the P-type monocrystalline silicon substrate 1, and the aluminum electrodes 4 are formed by printing aluminum paste on the back side of the P-type monocrystalline silicon substrate 1, followed by drying and sintering to form the electrodes. In one or more embodiments, the electrodes can adopt a gridline structure, including busbars and fingers, where the busbars perpendicularly intersect the fingers. The current generated by the TOPCon cell is first collected by the fingers and ultimately gathered by the busbars and transmitted out. If the TOPCon cell is not in a square shape, the busbars are generally arranged in a direction parallel to the longer edge of the cell. The spacing between the fingers is generally smaller than that between the busbars. FIG. 1 and FIG. 2 are schematic cross-sectional diagrams of the TOPCon cell in a direction parallel to the front busbars/back busbars, where the front busbars and the back busbars are omitted. In one or more embodiments, the first electrodes or silver electrodes 3 refer to electrodes arranged on the front fingers, while the second electrodes or aluminum electrodes 4 refers to electrodes arranged on the back fingers.

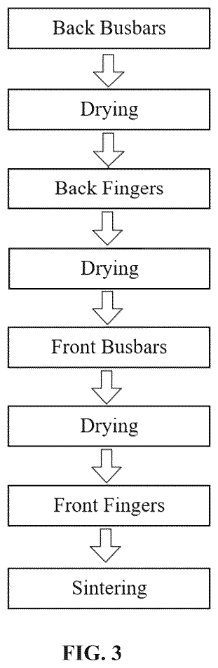

As shown in FIG. 3, the electrodes of the TOPCon cell are formed in the sintering process after screen printing. In the screen printing process, silver paste is first printed on the back busbars of the cell, which enters the drying equipment after printing for drying. After drying, aluminum paste is printed on the back fingers, which then enters the drying equipment for drying. The substrate is then flipped, and silver paste is printed on the front busbars, which enters the drying equipment for drying. After drying, silver paste is printed on the front fingers, which then enters the sintering process. After the sintering process, the silver electrodes 3 are formed on the front side of the substrate, and the aluminum electrodes 4 are formed on the back side.

The solid content of the silver paste is 90% to 92%, and the solid content of the aluminum paste is 70% to 85%.

The waste gases generated during the printing and sintering processes are mainly organic gaseous substances volatilized from organic solvents in the paste, and the generation of organic substances is closely related to the composition and content of the paste. Silver and aluminum pastes are mainly composed of powder, organic systems, and glass powder. During the sintering process, the organic system volatilizes, and the glass melts. Directly replacing the paste does not increase other waste gases. Therefore, using existing drying equipment is sufficient to handle waste gases, and it does not increase the cost of treating waste gases. Also, changing the paste does not alter the printing pattern, and the printing equipment does not need to be changed.

In existing technology, the front side of the substrate is arranged with electrodes by sintering silver-aluminum paste, and the back side of the substrate is arranged with electrodes by sintering silver paste. By replacing the silver-aluminum paste on the front side with silver paste and the silver paste on the back side with aluminum paste, as shown in FIG. 1 and FIG. 2, the production costs can be reduced by about 20 times, and the conversion efficiency of TOPCon is reduced by about 0.2%. This approach has practical value.

Although the production costs can be reduced by about 20 times, significantly enhancing product competitiveness, the increased line resistance of the aluminum paste and the contact resistance between Al/Si can result in efficiency losses due to fill factor (FF) loss compared to conventional TOPCon cells. This can be mitigated by optimizing the design of back pattern and improving the paste to compensate for the increased back contact resistance, thereby reducing the loss in conversion efficiency.

Based on the current cost of silver-aluminum paste being comparable to silver paste, replacing the paste for front fingers with silver paste can reduce contact resistance and line resistance, thereby improving efficiency. The contact resistance ρc of Ag/Si is approximately 0.05 Ω·cm², the contact resistance ρc of Ag/Al is approximately 3×10⁻² Ω·cm², and the contact resistance ρc of Ag/Ag is approximately 5×10⁻⁴ Ω·cm². Due to the presence of the tunnel oxide layer on the front side, the SE process of the conventional TOPCon cell can be eliminated, maintaining efficiency improvements while bringing cost advantages. Additionally, directly replacing silver paste with aluminum paste does not change the durability of TOPCon cells. Moreover, the screen printing process involves applying the paste through a patterned screen onto the substrate. When the substrate is directly placed under a patterned screen, the paste is squeezed through the mesh of the screen by a squeegee and printed onto the substrate to obtain the desired pattern. Therefore, the electrode preparation process remains unchanged, and the time required for electrode preparation remains unchanged as well since such time is not dependent on the type of paste used.

In some embodiments, the thickness of the silver electrode 3 ranges from 6 to 14 m, and the thickness of the aluminum electrode 4 ranges from 6 to 30 m. When the thickness of the silver electrode 3 and the aluminum electrode 4 is within such range, the TOPCon cell structure can maintain good conversion efficiency. The maximum width of the silver electrode 3 and the aluminum electrode 4 is determined by the size of current photovoltaic solar cells. For example, for a 182 mm-sized cell, the typical length is 180.6 mm. The minimum width of the silver electrode 3 and the aluminum electrode 4 are closely related to the screen openings. In some embodiments, the width of the silver electrode 3 ranges from 15 μm to 35 μm, and the width of the aluminum electrode 4 ranges from 15 μm to 170 μm.

The thickness of the printing paste is largely related to the total thickness of the screens, which are primarily prepared based on the requirements of electrode fabrication. The printing pressure is approximately 40N to 50N. After printing, drying is performed to prevent interference with subsequent printing processes. The temperature required for drying the back busbars, back fingers, front busbars, and front fingers is approximately 250° C. to 300° C. The speed at which the substrate is conveyed in the drying equipment is 12500 mm/min, depending on the printing CT time. Generally, the time required for drying the substrate is 8 to 15 seconds.

As shown in FIG. 1 and FIG. 2, the substrate can be either a P-type monocrystalline silicon substrate 1 or an N-type monocrystalline silicon substrate 2.

Since the silver paste contacts the P-type polycrystalline silicon, which has many holes, and the aluminum paste has strong reducibility, the contact between the P-type polycrystalline silicon and the aluminum paste is better, thereby reducing the Ag/P+-Si ohmic contact problem. Replacing the silver paste with an aluminum paste does not increase the difficulty of electrode matching, and the yield rate remains at the existing level.

Moreover, the size of the printing cross-sectional area greatly affects the line resistance. In other words, the line resistance can be altered by adjusting the size of the printing cross-sectional area.

When the structure of the front and back sides are symmetrical, the Al/Si contact resistance can reach 1.4-1.8 mΩ·cm², which is comparable to the Ag/Si contact resistance of 1.4-1.7 mΩ·cm². The Al line resistance (with a cross-sectional area of 1600 um²) is 0.7 Ω/cm, and the Ag line resistance (with a cross-sectional area of 163 um²) is 1.4 Ω/cm. Thus, the difference in line resistance can be optimized through adjustments to the printing area and paste quality, thereby compensating for the conversion efficiency. Specifically, the quality of the paste can be improved by enhancing the quality of aluminum powder, which in turn improves line resistance, contact resistance, etc. The Al/Si ohmic contact can be reduced by adjusting the content and composition ratio of the glass system. The printing quality can be adjusted by modifying the organic components. All of these adjustments can be continuously made and updated in the paste to enhance the conversion efficiency.

As shown in FIG. 1 and FIG. 2, during the preparation of TOPCon cells, the first tunnel oxide layer 5 is first prepared on the front side of the P-type monocrystalline silicon substrate 1. The first tunnel oxide layer 5 facilitates carrier tunneling, which can reduce the carrier recombination rate on the front surface of the TOPCon cell, thereby enhancing the open-circuit voltage and short-circuit current of the TOPCon cell, and thus improving the photoelectric conversion efficiency of the TOPCon cell. The process time for preparing the first tunnel oxide layer 5 is approximately 185 seconds, the process pressure is 1800 mTorr, and the nitrous oxide flow rate is approximately 9600 sccm.

Then, an N-type polycrystalline silicon layer 6 is arranged on the first tunnel oxide layer 5. The thickness of the N-type polycrystalline silicon layer 6 is approximately 120 nm. The process time for preparing the N-type polycrystalline silicon layer 6 is approximately 1045 seconds, the process pressure is 3100 mTorr, and the flow rate (sccm) ratio is approximately: silane:hydrogen:phosphine=2420:10268:322.

Then, a first silicon nitride layer 7 is arranged on the N-type polycrystalline silicon layer 6. The thickness of the first silicon nitride layer 7 is approximately 80 nm. The process time for preparing the first silicon nitride layer 7 is approximately 653 seconds, the process pressure is 1500 mTorr, and the flow rate (sccm) ratio is approximately: silane:ammonia=1800:9600.

Then, silver paste is applied to the first silicon nitride layer 7 for drying. After drying is completed, the back side of the substrate is further arranged. First, the second tunnel oxide layer 8 is prepared on the back side. The thickness of the second tunnel oxide layer 8 is approximately 2 nm. Similarly, the second tunnel oxide layer 8 facilitates carrier tunneling. The second tunnel oxide layer 8 can reduce the carrier recombination rate on the back surface of the TOPCon cell, thereby enhancing the open-circuit voltage and short-circuit current of the TOPCon cell, and thus improving the photoelectric conversion efficiency of the TOPCon cell. The process time for preparing the second tunnel oxide layer 8 is approximately 185 seconds, the process pressure is 1800 mTorr, and the nitrous oxide flow rate is approximately 9600 sccm.

Then, a P-type polycrystalline silicon layer 9 is arranged on the second tunnel oxide layer 8. The thickness of the P-type polycrystalline silicon layer 9 is approximately 120 nm. The process time for the P-type polycrystalline silicon layer 9 is approximately 1045 seconds, the process pressure is 3100 mTorr, and the flow rate (sccm) ratio is approximately: silane:hydrogen:phosphine=2420:10268:322.

Then, a second silicon nitride layer 10 is arranged on the P-type polycrystalline silicon layer 9. The thickness of the second silicon nitride layer 10 is approximately 80 nm. The process time for the second silicon nitride layer 10 is approximately 653 seconds, the process pressure is 1500 mTorr, and the flow rate (sccm) ratio is approximately: silane:ammonia=1800:9600.

Then, aluminum paste is applied to the back side for drying, and after drying, the substrate enters the sintering process. After the sintering process is completed, the silver electrodes 3 are formed on the front side of the substrate, and the aluminum electrodes 4 are formed on the back side.

The preparation method of a TOPCon cell structure includes the following steps:
Step S1: Provide a substrate comprising a front side and a back side;
Step S2: Perform texturing and cleaning on the substrate to form a pyramidal textured surface on the substrate, and obtain a first substrate;
Step S3: Prepare a first tunnel oxide layer on the front side of the first substrate;
Step S4: Deposit a doped poly-Si film that acts as a passivation layer on the front side of the first tunnel oxide layer using SiH₄, H₂, and PH₃, form an N-type polycrystalline silicon layer on the first tunnel oxide layer, and obtain a second substrate;
Step S5: Perform pre-annealing treatment on the second substrate, and obtain a third substrate;
Step S6: Perform etching treatment on the back side and sidewalls of the third substrate until exposing the back side of the third substrate, perform alkali polishing on the third substrate, and obtain a fourth substrate;
Step S7: Prepare a second tunnel oxide layer on the back side of the fourth substrate, and obtain a fifth substrate;
Step S8: Deposit a doped poly-Si film that acts as a passivation layer on the back side of the fifth substrate using SiH₄, H₂, and B₂H₆, form a P-type polycrystalline silicon layer on the second tunnel oxide layer, and obtain a sixth substrate;
Step S9: Perform post-annealing treatment on the sixth substrate, and obtain a seventh substrate;
Step S10: Clean the front side and sidewalls of the seventh substrate, perform RCA cleaning on the seventh substrate, and obtain the eighth substrate;
Step S11: Prepare a first silicon nitride layer on the front side of the eighth substrate and a second silicon nitride layer on the back side of the eighth substrate, and obtain a ninth substrate;
Step S12: Enter a screen printing process for the ninth substrate, form a plurality of first electrodes on the front side and a plurality of second electrodes on the back side of the ninth substrate, and obtain a tenth substrate;
Step S13: Perform sintering treatment on the tenth substrate, perform light injection treatment on the tenth substrate, and obtain the TOPCon cell;
Step S14: Test the TOPCon cell and classify and package the TOPCon cell according to the test results, and store the packaged TOPCon cells.

The purpose of step S4 is to prepare the N-type polycrystalline silicon 6 on the front side of the substrate after preparing the first tunnel oxide layer 5. Due to band bending blocking the movement of holes to the front side, while electrons can tunnel through the heavily doped n+type polycrystalline silicon, an electron transport layer is formed. In conventional diffusion preparation of PN junctions, the process is often paired with SE techniques to improve conversion efficiency, which involves forming local heavy doping at the location of metal grid lines and light doping elsewhere. Compared to the traditional diffusion formation of PN junctions, the new process provided in this invention has an electron transport channel, eliminating the need for SE techniques and reducing machine costs.

On the other hand, due to the low solubility of boron atoms in the silicon substrate, boron diffusion process in existing technology is difficult and time-consuming. The preparation of N-type polycrystalline silicon layer 6 in this invention can save process time, enhance capacity while improving the yield rate. Moreover, conventional TOPCon cells have an Al₂O₃ passivating layer on the front surface. Using current burn-through paste, direct contact between metal and Si substrate would result in efficiency loss. The new structure provided in this invention has a passivation contact structure consisting of SiO₂ and poly-Si layer, which provides a strong passivation effect and is beneficial for improving conversion efficiency. According to test data, with the presence of an electron transport channel, Ag—Si contact resistance can be reduced to 0.22Ω, showing significant advantages compared to the conventional diffusion process where the Ag—Si contact resistance is 0.75Ω, thereby enhancing conversion efficiency.

In step S8, compared to existing TOPCon processes, the main difference is changing the N-type polycrystalline silicon to P-type polycrystalline silicon. The purpose is to use band bending to block the movement of electrons to the back side, while holes can tunnel through the thin tunnel oxide layer and through the heavily doped p+type polycrystalline silicon, thereby forming a hole transport layer. Good contact with Al paste in the metallization process can further reduces the Al-Si contact resistance and compensating for the efficiency loss caused by increased Al metal grid line resistance.

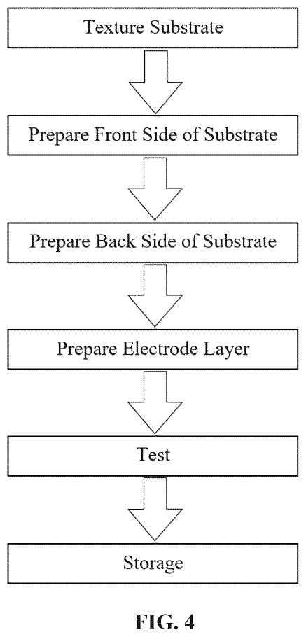

Specifically, as shown in FIG. 4, a substrate needs to be selected first. The substrate can be either a P-type monocrystalline silicon substrate 1 or an N-type monocrystalline silicon substrate 2. After the specific selection, texturing treatment is performed on the selected substrate. By performing texturing treatment on the silicon wafer, the reflectivity of the silicon wafer surface to incident sunlight can be reduced and the absorption of sunlight by the silicon wafer can be increased, thereby enhancing the conversion efficiency of photovoltaic cells.

The texturing treatment is performed in a tank-type monocrystalline texturing machine, which includes various modules such as pre-cleaning, texturing, post-cleaning, acid cleaning, slow pulling, and drying in the process sequence. The entire operation process runs automatically. During production, the substrate is placed in a silicon wafer box. An automatic substrate flipping machine orderly loads the silicon wafers into a wet basket. The wet basket is automatically transported into the texturing machine, and sequentially passes through the various modules, including pre-cleaning, texturing, post-cleaning, acid cleaning, slow pulling, drying tank. The equipment automatically controls the replenishment of acid, alkali etchant, and pure water in each process tank, and periodically discharges acid, alkali wastewater to maintain the activity of the etchant in the process tank to meet the process requirements. The main chemical reaction occurring during the monocrystalline texturing process is: Si+2NaOH+H₂O→Na₂SiO₃+2H₂↑.

Generally, equipment such as texturing mainframe equipment, texturing automation loading equipment and unloading equipment are used to perform texturing treatment on the substrate. The main parameters for the texturing treatment are: time approximately 420 seconds, temperature approximately 82° C., alkali volume fraction approximately 1.26%, ADD volume fraction approximately 0.63%. This allows the formation of a pyramidal textured surface on both the front and back sides of the substrate.

When the substrate texturing is completed, it is necessary to form a first tunnel oxide layer 5 on the textured substrate. The first tunnel oxide layer 5 is formed by oxidizing the substrate with N₂O, resulting in a densely structured SiO₂ film with a thickness of approximately 2 nm grown on the substrate surface.

The first tunnel oxide layer 5 is generally formed by coating with silicon dioxide. The main purpose of the tunnel silicon dioxide layer is to form an excellent passivation layer on the front side of the substrate to reduce the carrier recombination rate on the front side of the substrate, thereby enhancing the open-circuit voltage and short-circuit current of the TOPCon cell, and thus improving the conversion efficiency of the photovoltaic cells.

Then, an N-type polycrystalline silicon layer 6 is formed on the first tunnel oxide layer 5. The N-type polycrystalline silicon layer 6 is a doped poly-Si film deposited through the reaction of SiH₄, H₂, and PH₃, serving as a protective layer. The thickness of the N-type polycrystalline silicon layer 6 is approximately 120 nm.

The entire coating process is performed inside a PECVD equipment. The automatic flipping machine inserts the substrate into a graphite boat, the program is started, and the equipment runs automatically. The gases required for the reaction process are supplied by the special gas station. The waste gas is processed and absorbed in the silane combustion tower and waste gas absorption tower after preliminary combustion treatment, then discharged through the exhaust pipe. The waste liquid is treated at the sewage treatment station.

The important process parameters for preparing the N-type polycrystalline silicon layer 6 are: tunnel oxide layer process time approximately 185 seconds, process pressure approximately 1800 mTorr, nitrous oxide flow rate approximately 9600 sccm; polycrystalline silicon layer process time approximately 1045 seconds, process pressure approximately 3100 mTorr, flow rate (sccm) ratio approximately: SiH₄:H₂:PH₃=2420:10268:322.

The equipment used to prepare the N-type polycrystalline silicon layer 6 includes PE-POLY mainframe equipment, PE-POLY automation equipment, and ferry machine. Using PE-POLY equipment, the processes of preparing the first tunnel oxide layer 5 and the N-type polycrystalline silicon layer 6 can be performed in the same equipment, simplifying the processes of preparing the first tunnel oxide layer 5 and the N-type polycrystalline silicon layer 6, thereby increasing production efficiency.

Then, pre-annealing treatment is performed on the substrate. The main function of pre-annealing is to convert the in-situ doped amorphous silicon in PE-POLY into polycrystalline silicon at high temperatures, thereby improving the conductivity of the film, reducing the parasitic light absorption, and enhancing efficiency. Generally, pre-annealing mainframe equipment and pre-annealing automation equipment are used to process the substrate.

After pre-annealing, the substrate enters the etching and alkali polishing processes. First, the oxide layer on the back side and sidewalls of the cell is etched away using HF in the chain etching equipment, exposing the silicon surface. During the etching process, the oxide layer on the front side of the cell is protected by a water film. This oxide layer is used as a masking layer for alkali polishing of the back side. The main chemical reaction occurring during the removal of the oxide layer is: SiO₂+6HF→H₂SiF₆+2H₂O. After removing the oxide layer on the back side and sidewalls of the cell, the mechanical transfer arm sequentially guides the photovoltaic cells into the wet basket. The wet basket then enters the etching tank in the rear section of the alkali polishing equipment, sequentially passing through the pre-wash tank, alkali polishing etching tank, alkali wash tank, and rinse tank. The entire production process runs automatically. The main chemical reaction is: Si+2NaOH+H₂O→Na₂SiO₃+2H₂↑.

The equipment automatically controls the replenishment of acid, alkali, and pure water in each module, and periodically discharges acid water containing hydrofluoric acid, hydrochloric acid, waste alkali water containing sodium hydroxide, and rinse wastewater. These wastewaters are combined with the wastewaters of the same type from the texturing section and treated at the wastewater station. To maintain a clean production environment in the workshop, a gas collection equipment is arranged to collect waste gases generated during the cleaning process. The waste gases generated during the process are collected by the machine's own gas collection equipment, then discharged to the packed absorption tower for treatment. Acidic waste gases are collected in the acid gas scrubbing tower for treatment, and alkaline waste gases are collected in the alkaline gas scrubbing tower for treatment. To maintain the absorption and removal rate of the scrubbing towers for waste gases, the scrubbing towers are periodically replaced with fresh water and chemicals.

The important process parameters for etching and alkali polishing are: time approximately 160 seconds; temperature approximately 60° C.; alkali volume fraction approximately 2.30%; ADD volume fraction approximately 0.42%. Generally, the equipment used includes: chain etching mainframe equipment, etching automation loading equipment, etching automation unloading and mechanical transfer arm, alkali polishing mainframe equipment, and alkali polishing automation equipment.

Then, the second tunnel oxide layer 8 is prepared on the back side of the substrate, the main purpose of the second tunnel oxide layer 8 is to prepare an excellent passivation layer on the back surface of the cell, to reduce the carrier recombination rate on the front surface of the cell, thereby enhancing the open-circuit voltage and short-circuit current of the cell, and thus improving the photoelectric conversion efficiency of the photovoltaic cell.

The second tunnel oxide layer 8 is formed by oxidizing the substrate with N₂O, resulting in a densely structured SiO₂ film with a thickness of approximately 2 nm grown on the substrate surface.

Subsequently, a P-type polycrystalline silicon layer 9 is prepared on the second tunnel oxide layer 8. The P-type polycrystalline silicon layer 9 is a doped poly-Si film deposited through the reaction of SiH₄, H₂, and B₂H₆, serving as a protective layer. The thickness of the P-type polycrystalline silicon layer 9 is approximately 120 nm.

The entire coating process is performed inside a PECVD equipment. The automatic flipping machine inserts the silicon wafer into a graphite boat, the program is started, and the equipment runs automatically. The gases required for the reaction process are supplied by the special gas station. The waste gas is processed and absorbed in the silane combustion tower and waste gas absorption tower after preliminary combustion treatment, then discharged through the exhaust pipe. The waste liquid is treated at the sewage treatment station.

Important process parameters: the second tunnel oxide layer 8 process time is approximately 130 seconds, process pressure is approximately 1818 mTorr, nitrous oxide flow rate is approximately 8800 sccm; P-type polycrystalline silicon layer 9 process time is approximately 1070 seconds, process pressure is approximately 3100 mTorr, flow rate (sccm) ratio is approximately SiH₄:H₂:B₂H₆=2420:9196:1430.

The equipment used includes PE-POLY mainframe equipment, PE-POLY automation equipment, and ferry machine.

Then, post-annealing treatment is performed on the substrate. The silicon thin films grown by PECVD need to undergo high-temperature annealing treatment to improve the quality of the film, thereby enhancing the conversion efficiency of the cell. The equipment used for post-annealing includes: post-annealing mainframe equipment and post-annealing automation equipment.

Then, etching and RCA cleaning need to be performed on the substrate. First, a chain cleaning equipment is used to remove silicon oxide layer from the first tunnel oxide layer 5 and the sidewalls. Then, an automatic flipping machine is used to place the substrate into the wet basket. The basket is then placed in an alkali tank to etch off the silicon film plated on the front side and sidewalls of the silicon wafer during plating. Next, an acid etching solution is used to clean the silicon oxide mask layer on the front side and the oxide layer on the back side. After the cleaned silicon wafers are collected, they are sent to the coating section to complete coating of the silicon nitride protective layer. The equipment used includes chain etching mainframe equipment, etching automation loading equipment, etching automation unloading and mechanical transfer arm, RCA mainframe equipment, and RCA automation equipment.

Then, the second silicon nitride layer 10 needs to be coated on the P-type polycrystalline silicon layer 9. The main purpose of the second silicon nitride layer 10 is to provide an excellent antireflective layer on the surface of the cell to reduce the reflectivity of the cell surface to incident light, thereby enhancing the open-circuit voltage and short-circuit current of the cell, and thus achieving the purpose of enhancing the conversion efficiency of the cell. Through the reaction of SiH₄ and NH₃, a densely structured Si₃N₄ film of approximately 80 nm is formed on the surface of the silicon wafer. This process is performed inside a PECVD equipment. The automatic flipping machine loads the silicon wafers to be coated into the graphite boat, the program is started, and the equipment runs automatically. The SiH₄ and NH₃ required for the reaction are supplied by the special gas station. The waste gases generated by the reaction are discharged into the silane combustion tower for treatment, and after meeting standards, they are discharged through the exhaust pipe.

Important process parameters: the coating process time is approximately 620 seconds, process pressure is approximately 1750 mTorr, flow rate (sccm) ratio is approximately: SiH₄:NH₃=2250:11000.

The equipment used to prepare the second silicon nitride layer 10 includes a front film mainframe equipment, front film automation equipment, back film mainframe equipment, and back film automation equipment.

Then, the substrate needs to undergo a screen printing process. The main purpose of the screen printing process is to form metallized electrodes on the front and back sides of the cell to conduct out the photogenerated carriers produced under light illumination in the cell. The main equipment is a screen printing machine, which sequentially prints the paste on the back and front sides of the photovoltaic cell and dries them respectively. Both the printing and drying areas are equipped with gas collection equipment to capture the organic waste gases volatilized from the paste during the printing and drying processes. After treatment in the activated carbon absorption tower, the waste gases are discharged through the exhaust pipe. The activated carbon rods are replaced regularly to maintain the absorption efficiency of the activated carbon absorption tower.

The silver electrodes 3 on the front side of the substrate and the aluminum electrodes 4 on the back side of the substrate can be formed in screen printing process. As shown in FIG. 3, the preparation of metallized electrodes generally includes four printing, three drying, and one sintering processes. First, the back busbars of the cell is printed using silver paste. After a first drying process, the back fingers is printed using aluminum paste. After a second drying process, the front busbars is printed using silver paste. After a third drying process, the front fingers is printed using silver paste. Then the substrate enters a sintering process. After the sintering process is completed, the TOPCon cell is obtained.

The purpose of sintering is to sinter the metal paste printed on the substrate into metallized electrodes at high temperatures to ultimately form ohmic contact between the electrodes and the silicon. This process is performed inside a sintering furnace. At high temperatures, the organic solvents in the paste completely volatilize, and the paste and silicon form a melt. After cooling, good electrical contact are formed. The sintering waste gas is first treated in a combustion tower above the exhaust pipe, then further treated in an external waste gas treatment tower. The equipment used for the sintering process includes a sintering furnace light injection integrated machine.

Then, the sintering furnace light injection integrated machine is used to perform light injection treatment on the TOPCon cell. The main purpose of light injection is to enhance the stability of the photovoltaic cells. Under high temperatures, the photovoltaic cells are exposed to intense light. After this treatment process, the stability of the photovoltaic cells are greatly enhanced, with low light-induced and electric-induced degradation. After light injection is completed, the photovoltaic cells are tested and classified.

Offline testing using a testing machine is performed on the produced monocrystalline cells for appearance testing, efficiency testing, and EL testing. The photovoltaic cells are classified based on the conversion efficiency, open-circuit voltage, EL characteristics, and appearance characteristics of the cells, and the same types of photovoltaic cells are packaged together. The same types of photovoltaic cells are packaged together and labeled with battery information on the packaging box. The small boxes of photovoltaic cells are packed into large boxes and labeled. The packaged finished batteries are stored. The temperature and humidity in the warehouse are controlled within a certain range to ensure the quality of the photovoltaic cells.

During the handling process, AGV handling systems, AGV automatic packaging lines, intelligent warehousing, and unmanned handling systems are usually used.

The foregoing descriptions of specific exemplary embodiments of the present invention are presented for purposes of illustration and description. These descriptions are not intended to limit the invention to the precise form disclosed, and it is apparent that many modifications and variations are possible in light of the above teaching. The purpose of selecting and describing the exemplary embodiments is to explain the specific principles of the invention and its practical application, thereby enabling those skilled in the art to realize and utilize various different exemplary embodiments of the invention as well as various alternatives and modifications. The scope of the invention is intended to be defined by the claims and their equivalents.

What is claimed is:

1. A solar cell structure comprising: a substrate, the substrate comprising a front side and a back side, wherein a first tunnel oxide layer, a first polycrystalline silicon layer, a first silicon nitride layer, and a plurality of first electrodes are sequentially formed on the front side of the substrate, a second tunnel oxide layer, a second polycrystalline silicon layer, a second silicon nitride layer, and a plurality of second electrodes are sequentially formed on the back side of the substrate.

2. The solar cell structure of claim 1, wherein the first polycrystalline silicon layer is an N-type polycrystalline silicon layer, and the second polycrystalline silicon layer is a P-type polycrystalline silicon layer.

3. The solar cell structure of claim 2, wherein the plurality of first electrodes comprise a plurality of silver fingers, and the plurality of second electrodes comprise a plurality of aluminum fingers.

4. The solar cell structure of claim 3, wherein the plurality of first electrodes further comprise a plurality of first silver busbars, and the plurality of second electrodes further comprise a plurality of second silver busbars, and wherein the plurality of first silver busbars are perpendicular to the plurality of silver fingers, and the plurality of second silver busbars are perpendicular to the plurality of aluminum fingers.

5. The solar cell structure of claim 3, wherein the substrate is a P-type monocrystalline silicon substrate.

6. The solar cell structure of claim 5, wherein a thickness of each of the plurality of silver fingers is in a range of 6 μm to 14 μm.

7. The solar cell structure of claim 5, wherein a thickness of each of the plurality of aluminum fingers is in a range of 6 μm to 30 μm.

8. The solar cell structure of claim 5, wherein a width of each of the plurality of silver fingers is in a range of 15 μm to 35 μm.

9. The solar cell structure of claim 5, wherein a width of each of the plurality of aluminum fingers is in a range of 15 μm to 170 μm.

10. The solar cell structure of claim 3, wherein the substrate is an N-type monocrystalline silicon substrate.

11. The solar cell structure of claim 10, wherein a thickness of each of the plurality of silver fingers is in a range of 6 μm to 14 μm.

12. The solar cell structure of claim 10, wherein a thickness of each of the plurality of aluminum fingers is in a range of 6 μm to 30 μm.

13. The solar cell structure of claim 10, wherein a width of each of the plurality of silver fingers is in a range of 15 μm to 35 μm.

14. The solar cell structure of claim 10, wherein a width of each of the plurality of aluminum fingers is in a range of 15 μm to 170 μm.

15. A preparation method for a solar cell structure comprising:
providing a substrate comprising a front side and a back side;
forming a first tunnel oxide layer on the front side of the substrate;
depositing a first polycrystalline silicon layer on the first tunnel oxide layer;
forming a second tunnel oxide layer on the back side of the substrate;
depositing a second polycrystalline silicon layer on the second tunnel oxide layer;
forming a first silicon nitride layer on the first polycrystalline silicon layer and a second silicon nitride layer on the second polycrystalline silicon layer; and
forming a plurality of first electrodes on the first silicon nitride layer and a plurality of second electrodes on the second silicon nitride layer.

16. The preparation method of claim 15, wherein the first polycrystalline silicon layer is an N-type polycrystalline silicon layer, and the second polycrystalline silicon layer is a P-type polycrystalline silicon layer.

17. The preparation method of claim 16, wherein the plurality of first electrodes comprise a plurality of silver fingers, and the plurality of second electrodes comprise a plurality of aluminum fingers.

18. The preparation method of claim 17, wherein the plurality of first electrodes further comprise a plurality of first silver busbars, and the plurality of second electrodes further comprise a plurality of second silver busbars, and wherein the plurality of first silver busbars are perpendicular to the plurality of silver fingers, and the plurality of second silver busbars are perpendicular to the plurality of aluminum fingers.

19. The preparation method of claim 15, wherein the method does not include a boron diffusion process.

20. The preparation method of claim 17, wherein the substrate is an N-type monocrystalline silicon substrate or a P-type monocrystalline silicon substrate.
